(19) United States
(12) Patent Application Publication
(10) Pub. No.: US 2010/0072627 A1
(43) Pub. Date: Mar. 25, 2010

(54) WAFER INCLUDING INTERCEPTING THROUGH-VIAS AND METHOD OF MAKING INTERCEPTING THROUGH-VIAS IN A WAFER

(75) Inventor: Albert WANG, Fort Collins, CO (US)

Correspondence Address: Kathy Manke;Avago Technologies Limited, 4380 Ziegler Road, Fort Collins, CO, 80525, US

(73) Assignee: Avago Technologies Wireless IP (Singapore) Pte. Ltd.

(21) Appl. No.: 12/237,665

(22) Filed: Sep. 25, 2008

(51) Int. Cl. H01L 23/48; H01L 21/4763

(52) U.S. Cl. 257/774; 438/637; 257/E23.01; 257/E21.495

(57) ABSTRACT

A semiconductor device includes a substrate; a first via provided in the substrate extending from a first side of the substrate to a first depth into the substrate, the first depth being less than a thickness of the substrate and the first via having a first width in one direction; a first conductive material provided in the first via; a second via provided in the substrate extending from a second side of the substrate to a second depth into the substrate, the second via having a second width in one direction, the second width being greater than the first width; and a second conductive material provided in the second via so as to form an electrical connection with the first conductive material provided in the first via.

### BACKGROUND

Through-wafer vias (also known by other names such as substrate vias, or through-vias, or backside vias) have been described and used for compound semiconductor integrated circuits for high frequency and high power applications. They provide a means to add a metal interconnect layer to the back of a wafer (e.g., a silicon, gallium arsenide (GaAs), indium phosphide, or other semiconductor wafer) to supplement the metal interconnect lines on the front side of the wafer, and their use is driven by multiple considerations. Often, the backside metal of a wafer is a solid sheet of metal which forms a voltage ground. This backside “ground plane” removes the need for ground lines on the top of the wafer, which would otherwise consume integrated circuit area and thus increase cost, and which may have unfavorable series resistance and inductance due to layout considerations which can degrade electrical performance, and which often need to be attached with bond wires which add to assembly costs. For high power applications, often backside ground planes can also drain additional heat away from the devices while under operation.

There are some considerations in the fabrication of through-vias and their applications whose impact can be observed in the reported literature, e.g. Bonneau et al., 2002 GaAs MANTECH, pp 113-16; Hendricks et al. 2002 GaAs MANTECH, pp 105-8. In general, these known through-vias are fabricated from the wafer backside after a desired amount or thickness of the backside of the wafer has been removed by backlapping or grinding the wafer. Alignment of through-vias from the backside to features on the front side tends to be crude, with an accuracy on the order of 1 to 10 μm, and the effective accuracy can become worse due to process bias such as the growth of features. By comparison, alignment accuracy between features on the wafer front side is typically less than 1 μm, and often on the order of 0.1 to 1 μm, which can depend on the technology and/or material that is employed. Therefore, through-vias normally terminate on much larger front side metal pads, which partially nullifies the area advantage of using through-vias.

Also, the processes used to etch these known through-vias impose considerations as well. In the past, through-vias have been produced by using a wet chemical etch (see, e.g. D'Asaro et al., IEEE TRANS. ELECTRON DEVICES v. 25 pp 1218-21 (1978). However, this method greatly expands the size of the through-via on the backside of the wafer and is now uncommon. Nowadays, through-vias more commonly are etched by a plasma-based etch through wafers which typically have been thinned to a thickness of 50 to 100 μm. Such plasma-based etches will slow down as the through-via sizes get smaller and as the through-via goes deeper into the wafer. This means that through-vias which are too small are impractical or impossible to etch, and typical through-via plan-view linear dimensions (i.e., “widths” of the through-vias) are on the order of 10 to 100 μm.

When a device has a terminal which is to be grounded by means of a through-via to a backside ground plane, in general it is desired to provide the through-via to be as close as possible to the ground terminal in order to reduce series resistance and/or inductance. For example, field-effect transistors (FETs) formed on the front surface may have a terminal to be grounded (typically the source for an n-type FET), and that terminal can be directly connected to a backside ground plane by a through-via.

FIG. 1A shows a cross-section view, and FIG. 1B shows a plan view, of an FET 100 produced on a wafer 10 which includes one or more through-vias 150. Wafer 10 includes a first (front) side 12 and a second side (backside) 14. A ground plane 16 is formed on backside 14 of wafer 10. When wafer 10 is ultimately diced into individual integrated circuit “chips,” the portion of each wafer 10 that is provided for each chip may be referred to as a substrate. FET 100 includes drain terminal(s) 110, gate terminal(s) 120 and source terminal(s) 130. As best seen in FIG. 1A, metalized through-vias 150 pass through wafer 10 to connect source terminal(s) 130 to ground plane 16.

Another type of device which often has one terminal connected to ground is a capacitor as a component of a passive network such as a filter. A through-via can make a direct connection between one terminal (e.g., the bottom plate) of a capacitor and a ground plane on the backside of a wafer.

FIG. 2A shows a cross-section view, and FIG. 2B shows a plan view, of a capacitor 200 produced on a wafer 20 which includes one or more through-vias 250. Wafer 20 includes a first (front) side 22 and a second side (backside) 24. A ground plane 26 is formed on backside 24 of wafer 20. As before, when wafer 20 is ultimately diced into individual integrated circuit “chips,” the portion of wafer 20 that is provided for each chip is sometimes referred to as the substrate. Capacitor 200 includes one or more bottom plate(s) 210, insulating layer(s) 220, and top plate(s) 230. As best seen in FIG. 2A, metalized through-vias 250 pass through wafer 20 to connect bottom plate(s) 210 to ground plane 26.

The construction shown in FIGS. 2A-B is sometimes called a capacitor-over-via. Such a connection may be advantageous from the standpoint of minimizing the area required to fabricate an integrated circuit, but it also means that part of the mechanical support of capacitor 200 has been removed. This reduction in mechanical support can lead to premature failure of capacitor 200.

Another consideration is the impact of adding a large number of through-vias to an integrated circuit. A large number of through-vias, especially if deployed in a line, can mechanically weaken the substrate so that it becomes easier to fracture during assembly.

So it would be desirable to provide a though-via for a wafer that can provide sufficient mechanical support and a reliable connection. It would also be desirable to provide a method of making such through-vias in a wafer. It would further be desirable to provide a wafer including one or more such through-vias.

### SUMMARY

In a representative embodiment, a method is provided for forming a through-via in a semiconductor wafer. The method comprises: forming a first via starting on a first side of a semiconductor wafer and extending a first depth into the semiconductor wafer from the first side of the semiconductor wafer, the first depth being less than a thickness of the semiconductor wafer and the first via having a first width in one direction; providing a first conductive material in the first via; providing one or more electronic components on the first side of the semiconductor wafer; forming a second via starting on a second side of the semiconductor wafer opposite the first side and extending a second depth into the semiconductor wafer from the second side of the semiconductor wafer so as to expose the first via, the second via having a second width in one direction, the second width being greater than the first width; and providing a second conductive material in the second via so as to make an electrical connection with the first conductive material deposited in the first via.

In another representative embodiment, a semiconductor device includes a substrate; a first via provided in the substrate extending from a first side of the substrate to a first depth into the substrate, the first depth being less than a thickness of the substrate and the first via having a first width in one direction; a first conductive material provided in the first via; a second via provided in the substrate extending from a second side of the substrate to a second depth into the substrate, the second via having a second width in one direction, the second width being greater than the first width; and a second conductive material provided in the second via so as to form an electrical connection with the first conductive material provided in the first via.

In another representative embodiment, an electrical device is provided on a substrate. The electrical device comprises: a first conductive electrode provided on a first side of the substrate; a first via provided in the substrate extending from the first side of the substrate to a first depth into the substrate, the first depth being less than a thickness of the substrate, and the first via having a first width in one direction; a first conductive material provided in the first via so as to form an electrical connection with the first conductive electrode; a second via provided in the substrate extending from a second side of the substrate to a second depth into the substrate, the second via having a second width in one direction, the second width being greater than the first width; and a second conductive material provided in the second via so as to form an electrical connection with the first conductive material provided in the first via.

### BRIEF DESCRIPTION OF THE DRAWINGS

The example embodiments are best understood from the following detailed description when read with the accompanying figures. It is emphasized that the various features are not necessarily drawn to scale. In fact, the dimensions may be arbitrarily increased or decreased for clarity of discussion. Wherever applicable and practical, like reference numerals refer to like elements.

FIGS. 1A-B show a field-effect transistor produced on a wafer which includes one or more through-vias.

FIGS. 2A-B show a capacitor produced on a wafer which includes one or more through-vias.

FIGS. 3A-J illustrate one embodiment of a process of producing a through-via in a wafer.

FIGS. 4A-B show a through-via in a wafer.

FIGS. 5A-B show one embodiment of a wafer which includes a through-via structure.

FIGS. 6A-B show an embodiment of a field-effect transistor produced on a wafer which includes a through-via structure.

FIGS. 7A-B show one embodiment of a capacitor produced on a wafer which includes a through-via structure.

### DETAILED DESCRIPTION

In the following detailed description, for purposes of explanation and not limitation, representative embodiments disclosing specific details are set forth in order to provide a thorough understanding of an embodiment according to the present teachings. However, it will be apparent to one having ordinary skill in the art having had the benefit of the present disclosure that other embodiments according to the present teachings that depart from the specific details disclosed herein remain within the scope of the appended claims. Moreover, descriptions of well-known apparatuses and methods may be omitted so as to not obscure the description of the example embodiments. Such methods and apparatuses are clearly within the scope of the present teachings.

Moreover, when used herein the context of describing a value or range of values, the terms “about” and “approximately” will be understood to encompass variations of ±10% with respect to the nominal value or range of values.

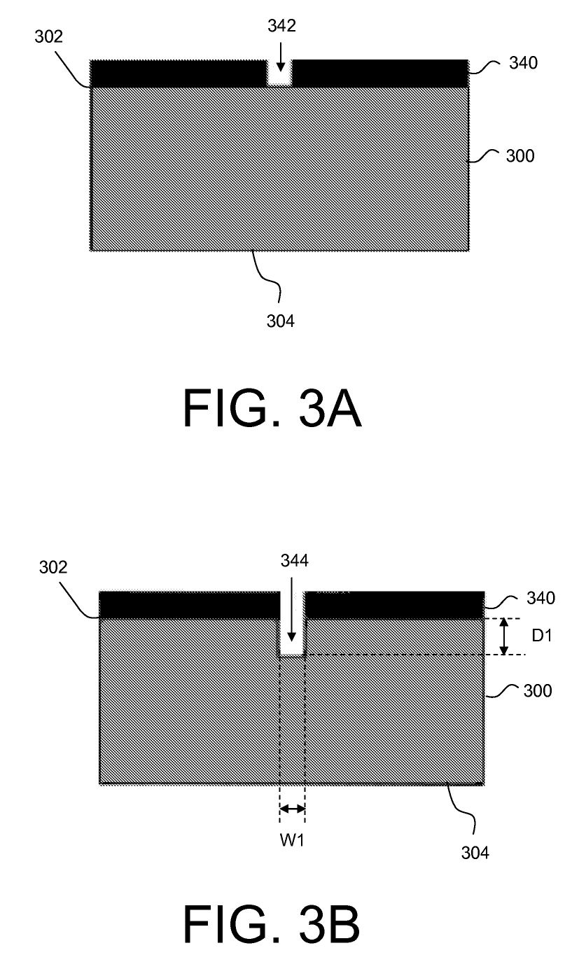

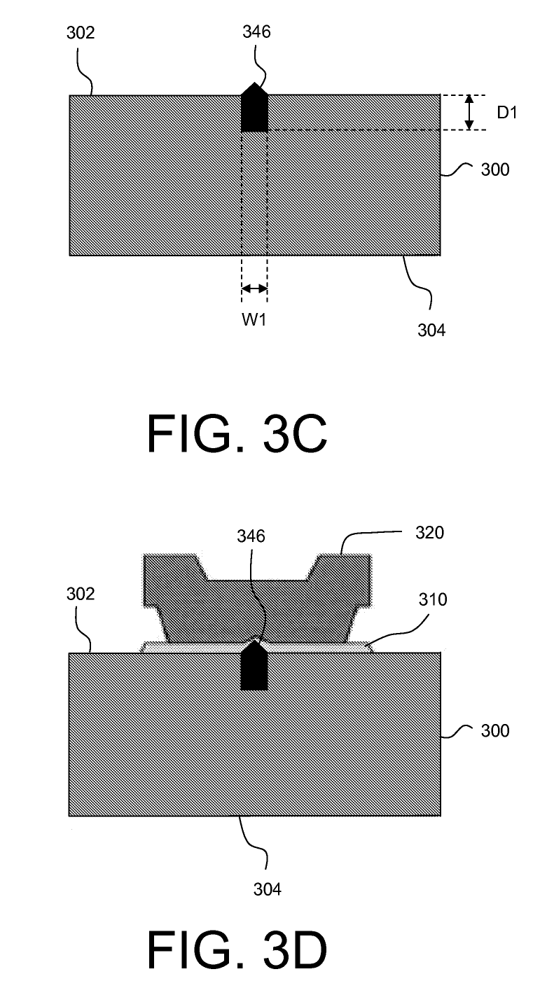

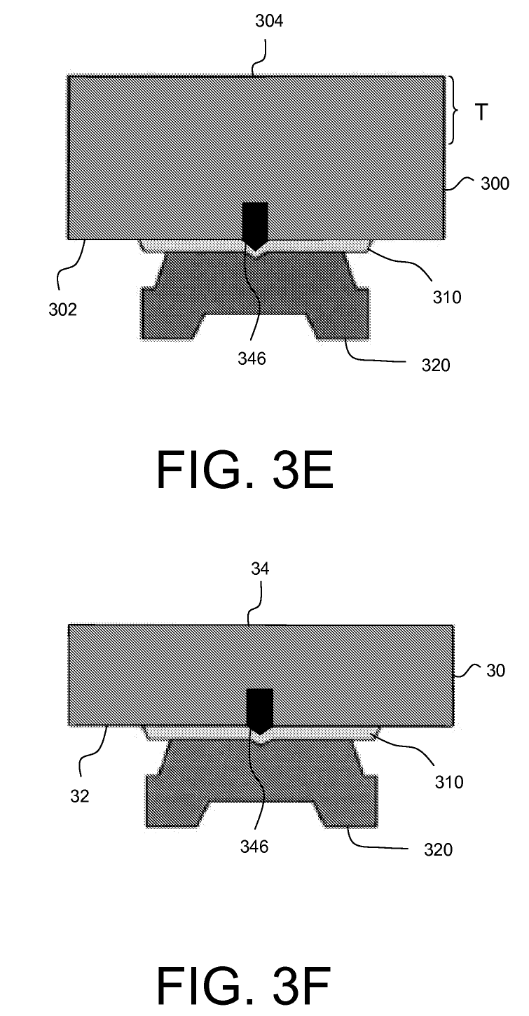

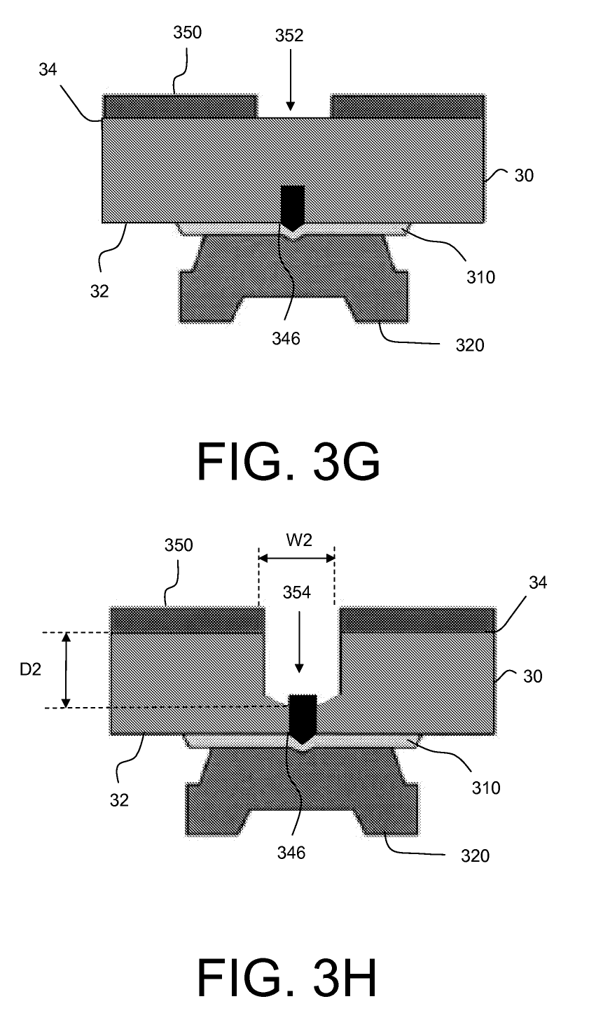

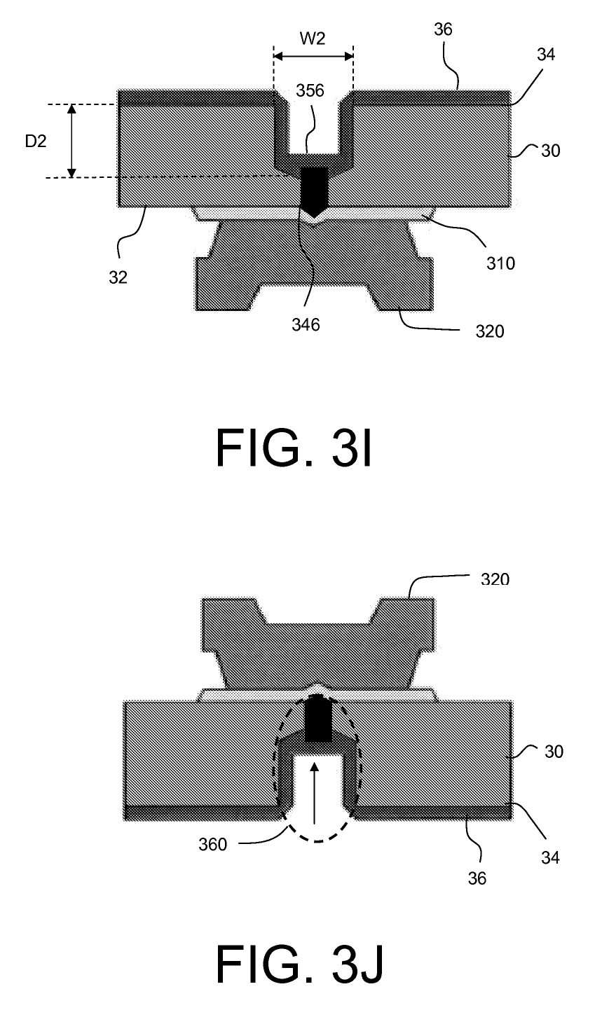

FIGS. 3A-J illustrate one embodiment of a process of producing a through-via in a wafer. Beneficially, the part of the process shown in FIGS. 3A-C is performed early in the processing of the wafer, since as the processing of the wafer continues, in general more space will be required between the front-side vias to be formed in this process and the various features or components that are formed on the front side of the wafer.

As shown in FIG. 3A, a patterned mask 340 is formed on a first (front) side 302 of a wafer 300 so as to have one of more openings 342 therein. Beneficially, wafer 300 is a semiconductor wafer, for example a silicon wafer, a gallium arsenide (GaAs) wafer, or an indium phosphide wafer.

Then, as shown in FIG. 3B, wafer 300 is etched so as to form one or more first vias or first trenches 344 in wafer 300. Beneficially, first via 344 is etched into wafer 300 from first side 302 of wafer 300 to a depth D1, where D1 is less than the thickness of wafer 300. Beneficially, first via 344 has a narrow width W1 in at least one dimension. In some embodiments, W1 may be about 5 μm. In one embodiment, wafer 300 is etched using an anisotropic plasma-based etch according to techniques that are known in the art.

Next, as shown in FIG. 3C, patterned mask 340 is removed from first side 302 of wafer 300 and a first conductive material (e.g., metal) 346 is deposited into first via 344 from first side 302 of substrate 300. Beneficially, first conductive material 346 is deposited into first via 344 so as to close the opening of first via 344 from first side 302 of wafer 300. In some embodiments, first conductive material 346 is deposited into first via 344 so as to completely fill first via 344.

At this point, the bottom of first via 344 terminates inside wafer 300 and is not connected to the second side (backside) 304 of wafer 300.

Then, as shown in FIG. 3D, first side 302 of wafer 300 is patterned and processed as necessary to construct any desired interconnections 310 and elements 320 (e.g., electronic components such as capacitors, transistors, resonators, diodes, conductors, connectors, etc.) to be formed thereon.

Next, as shown in FIG. 3E, wafer 300 is mounted upside down and a thickness “T” of wafer 300 is removed by lapping or grinding or another technique so as to thin the wafer.

As shown in FIG. 3F, the foregoing processes yield a thinned wafer 30 having a first side 32 and a second side (backside) 34, with first via 344 having first conductive layer 346 deposited therein extending from the first side 32 into thinned wafer 30 to a depth D1. Beneficially, after thinning, thinned wafer 30 has a thickness of 50-150 μm. In some embodiments, thinned wafer 30 has a thickness of about 100 μm. When thinned wafer 30 is ultimately diced into individual integrated circuit “chips,” the portion of each thinned wafer 30 that is provided for each chip may be referred to as a substrate.

Next, as shown in FIG. 3G, pattern mask 350 is formed on second side (backside) 34 of thinned wafer 30 so as to have one or more openings 352 therein.

Next, as shown in FIG. 3H, thinned wafer 30 is etched so as to form one or more second vias or second trenches 354 in thinned wafer 30. Beneficially, second via 354 is etched into wafer 30 from second side 34 of thinned wafer 30 to a depth D2 so as to expose the bottom of first via 344.

In some beneficial embodiments, where thinned wafer 30 has a thickness of about 100 μm the depth D2 may be greater than 75 μm. Meanwhile, beneficially, the depth D1 of first via 344 may be less than 20 μm. In some embodiments, D1 is between 10-20 μm.

In an advantageous feature, because second side (backside) 34 of wafer 30 does not generally have a large number of elements or features (indeed, in many cases it does not have any elements or features formed thereon) second via 354 does not need to be relatively narrow in at least one dimension. Beneficially, second via 354 has a width W2 in at least one dimension that is greater than W1. Accordingly, second via 354 can be formed with a larger width and therefore can be more easily etched to a particular depth. Also, because second via 354 can be formed with a larger width, alignment issues with respect to first via 344 are mitigated. In some embodiments, W2 may be about 30 μm.

Next, as shown in FIG. 3I, a second conductive material (e.g., a metal) is provided on second side (backside) 34 of wafer thinned 30 to form a ground plane 36 on second side (backside 34), and to form a conductive layer 356 inside of second via 354. In this case, second conductive layer 356 of the second conductive material may or may not completely fill second via 354, but beneficially provides an electrical connection between ground plane 36 and first conductive material 346 in first via 344.

Finally, FIG. 3J shows a completed intercepting through-via 360 for wafer 30 comprising first via 344 and second via 354 having first and second conductive materials deposited respectively therein in electrical connection with each other.

Although in the process described above with respect to FIGS. 3A-J interconnections 310 and elements 320 are formed after first via(s) 344 are formed and first conductive material 346 is deposited therein, in some embodiments some or all of the interconnections 310 and elements 320 may be formed before some or all of first via(s) 344 are formed and/or before first conductive material 346 is deposited therein or simultaneously with formation of some or all of first via(s) 344 or first conductive material 346.

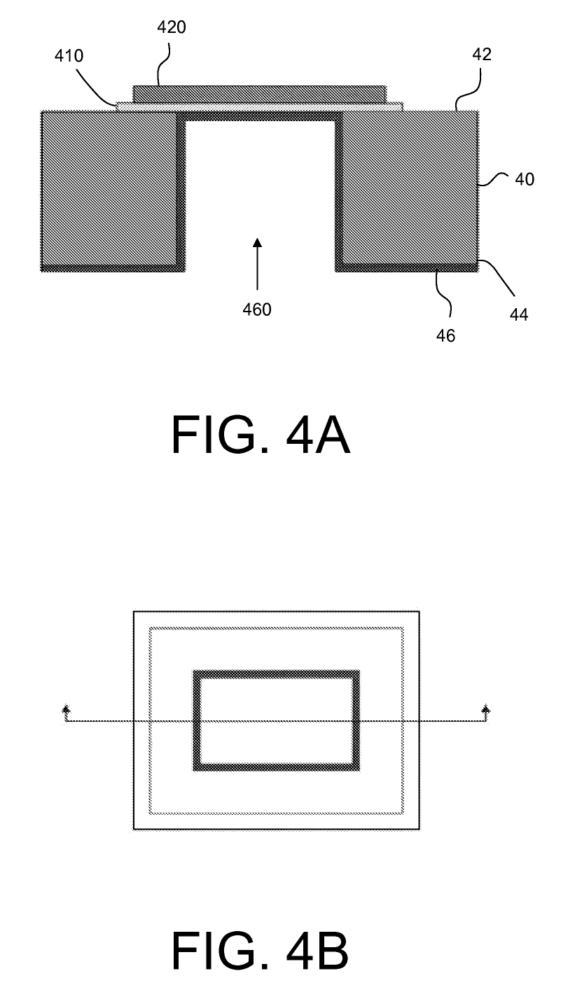

FIGS. 4A-B show a through-via 460 in a wafer 40 produced with a conventional process, for comparison to intercepting through-via 360 as described above. Interconnections 410 and elements (e.g., electronic components such as capacitors, transistors, resonators, diodes, conductors, connectors, etc.) 420 are formed on the top side 42 of wafer 40, and a ground plane 46 is formed on backside 44. The sides and bottom of through-via 460 are plated with the metallization of ground plane 46.

In some embodiments, intercepting through-vias produced by one or more embodiments of the method illustrated in FIGS. 3A-J may provide one or more of the following features. First vias 344 can be made with very narrow or small widths since they do not have penetrate all the way through wafer 30. Second vias 354 also can be made smaller since they too do not have penetrate all the way through wafer 30. Although such vias are smaller and therefore typically contain less metal, and consequently have greater series resistance and inductance values, the preservation of wafer material means that they can be deployed closer together and parallelized where necessary to lower the total impedance without adversely affecting the mechanical integrity of the wafer or substrate.

Because first vias 344 are aligned to first side 32, which normally has a much higher alignment accuracy than second side (backside) 34, first vias 344 can be deployed with smaller spacings to the elements or devices 320 on first side 32 of wafer 30. The problem of poor backside alignment accuracy moves to an intercept plane inside wafer 30 where first via 344 contacts second via 354, instead of being near the sensitive devices 320. Accordingly, in some embodiments, it may be possible to reduce the resistance and inductance to ground, because conventional through-vias 460 often only have metal formed on their sides (e.g., in a case where the metal is deposited by electroplating), whereas a collection of smaller first vias 344 may actually contain a larger total volume of conductive material (e.g., metal).

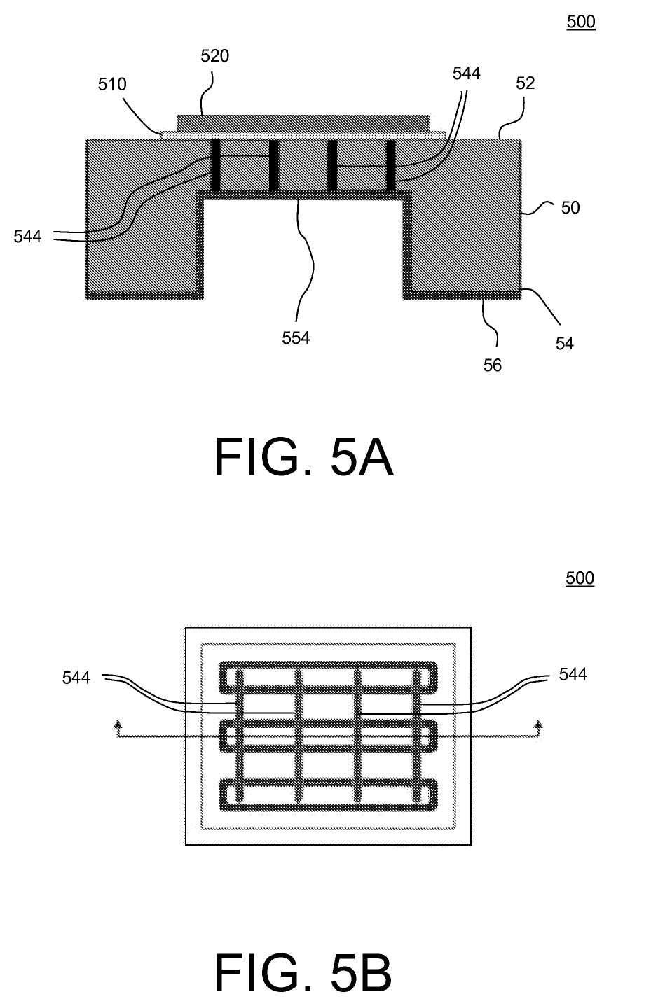

FIGS. 5A-B show an example of one embodiment of a wafer 50 which includes a through-via structure 500 comprising a plurality of top-side vias 544, each having a conductive material (e.g., metal) deposited therein and being connected to a backside via 554 having a second conductive material (e.g., metal) deposited therein. Interconnections 510 and elements 520 (e.g., electronic components such as capacitors, transistors, resonators, diodes, etc.) are formed on the first (top) side 52 of wafer 50, and a ground plane 56 is formed on second side (backside) 54. Ground plane 56 is electrically connected to the second conductive material deposited in second via 554. The top-side vias could all be connected to a same element 520, or different front-side vias could be connected to different elements 520.

Embodiments of intercepting through-vias as described above with respect to FIGS. 3A-J and FIGS. 5A-B can be employed in conjunction with a number of different types of components in an integrated circuit. Exemplary components include a field effect transistor having one terminal or electrode (e.g., a source) connected to ground, and a capacitor having one terminal or electrode connected to ground.

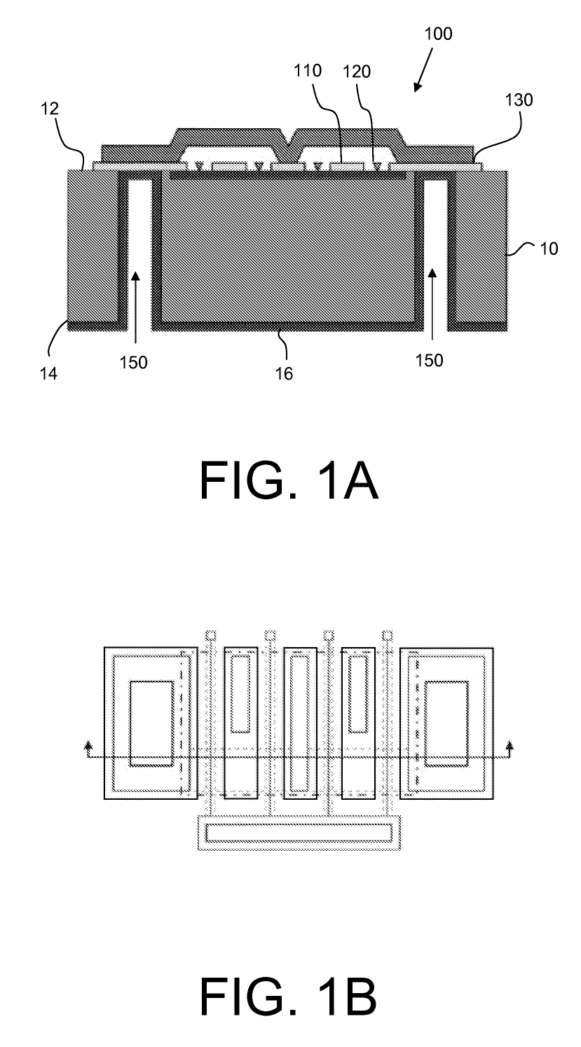

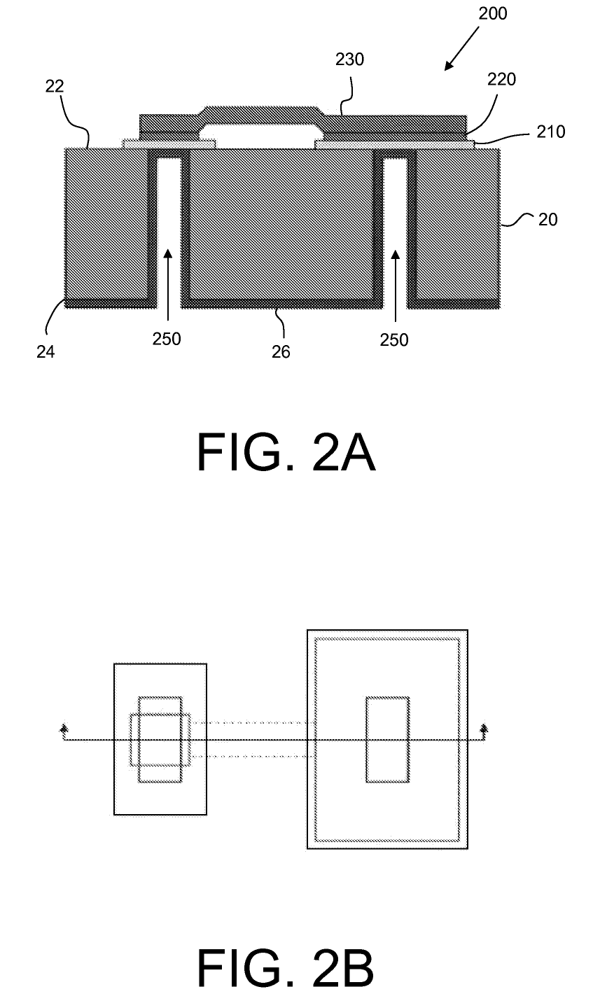

For example, a FET may have a number of source fingers each of which is to be connected to ground. It is generally desired to make each of the connections between the source fingers and ground with as low of a series impedance and series inductance as possible. A FET with conventional through-wafer vias will tend to have a small number of through-wafer vias connected to the source fingers with the other source fingers connected to these through-wafer vias with interconnects on the front side of the wafer, an example of which is shown in FIGS. 1A-B. Deploying a large number of conventional through-vias imposes an area penalty because of alignment difficulties, and/or will severely weaken the integrated circuit because too much wafer/substrate material is removed.

However, with intercepting through-wafer vias, it becomes possible to provide a through-vias for each source finger without consuming a large amount of area and while retaining the mechanical integrity of the integrated circuit.

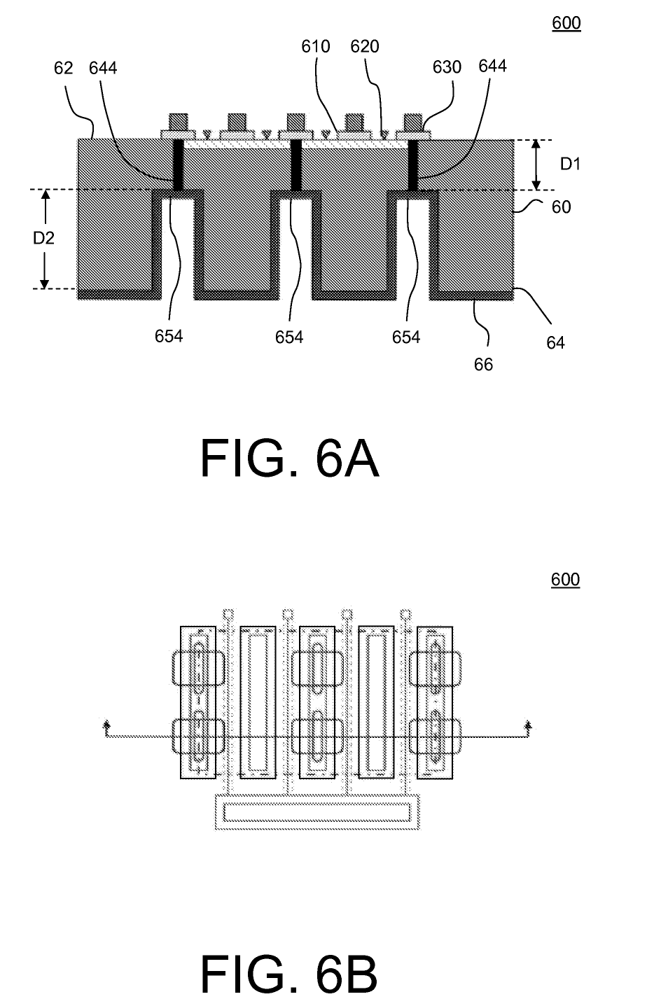

FIGS. 6A-B show one embodiment of a field-effect transistor (FET) 600 produced on a wafer 60 which includes a through-via structure. Wafer 60 includes a first (front) side 62 and a second side (backside) 64. A ground plane 66 is formed on second side 64 of wafer 60. When wafer 60 is ultimately diced into individual integrated circuit “chips,” the portion of each wafer 60 that is provided for each chip may be referred to as a substrate. FET 600 includes drain terminal(s) 610, gate terminal(s) 620 and source terminal(s) 630. Each drain terminal 610, gate terminal 620 and source terminal 630 comprises a conductive (e.g., metal) electrode.

As best seen in FIG. 6A, beneath each source terminal 630 is provided a first via 644 having a first conductive material deposited therein. The first conductive material in each first via 644 is electrically connected with the corresponding source terminal/electrode 630, and also electrically connected with a second conductive material deposited in a corresponding second via 654 formed on the second side (backside) 64 of wafer 60.

First vias 644 each extend from first side 62 of wafer 60 to a depth D1, where D1 is less than the thickness of wafer 60. Beneficially, D1 may be less than 20 μm. In some embodiments, D1 is between 10-20 μm. Beneficially, first via 644 has a narrow width in at least one dimension. In some embodiments, the width may be about 5 μm.

Second vias 654 are etched into wafer 60 from second side 64 of wafer 60 to a depth D2 so as to expose the bottom of a corresponding one of the first via 644. In some embodiments, D2 may be greater than 75 μm. In a beneficial arrangement, in some embodiments each second via 654 has a width in at least one dimension that is greater than the width of the corresponding first via 644, as shown in FIGS. 6A-B. In some embodiments, second via 654 has a width of about 30 μm.

As a result, in FIGS. 6A-B: a first source terminal/electrode 630 has a first via 644 beneath it that is electrically connected to a second via 654 beneath the first via 644 and which in turn is connected to a ground plane 66; a second source terminal/electrode 630 has a third via 644 beneath it that is electrically connected to a fourth via 654 beneath the third via 644 and which in turn is connected to the ground plane 66; etc.

The front side alignment accuracy of the intercepting through-via structure as described above also reduces the need for capacitor-over-vias. Rather than deploy a conventional through-via directly under a capacitor, small front side (first) vias can be deployed with close spacing to the capacitor.

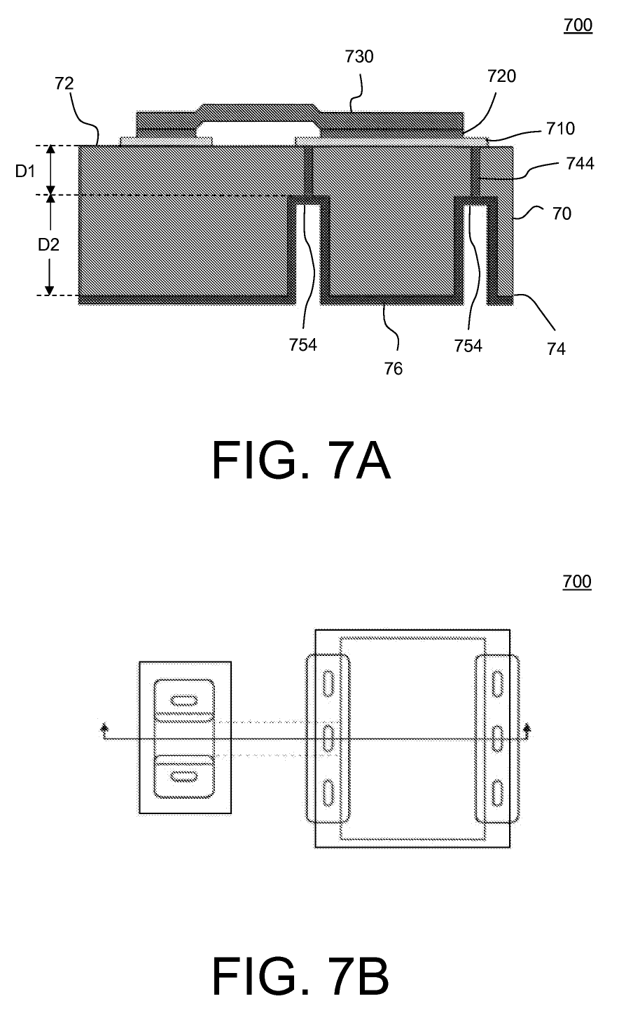

FIGS. 7A-B show one embodiment of a capacitor 700 produced on a wafer 70 which includes a through-via structure. Wafer 70 includes a first (front) side 72 and a second side (backside) 74. A ground plane 76 is formed on second side 74 of wafer 70. As before, when wafer 70 is ultimately diced into individual integrated circuit “chips,” the portion of wafer 70 that is provided for each chip is sometimes referred to as the substrate. Capacitor 700 includes one or more bottom plate(s) or conductive electrode(s) 710, insulating layer(s) 720, and top plate(s) or conductive electrode(s) 730.

As best seen in FIG. 7A, beneath bottom electrode 710 is provided one or more first vias 744 each having a first conductive material deposited therein. The first conductive material in each first via 744 is electrically connected with the bottom electrode 710, and also electrically connected with a second conductive material deposited in a corresponding second via 754 formed on the second side (backside) 74 of wafer 70.

First vias 744 each extend from first side 72 of wafer 70 to a depth D1, where D1 is less than the thickness of wafer 70. Beneficially, D1 may be less than 20 μm. In some embodiments, D1 is between 10-20 μm. Beneficially, first via 744 has a narrow width in at least one dimension. In some embodiments, the width may be about 5 μm.

Second vias 754 are etched into wafer 70 from second side 74 of wafer 70 to a depth D2 so as to expose the bottom of a corresponding one of the first via 744. In some embodiments, D2 may be greater than 75 μm. In a beneficial arrangement, in some embodiments each second via 754 has a width in at least one dimension that is greater than the width of the corresponding first via 744, as shown in FIGS. 7A-B. In some embodiments, second via 754 has a width of about 30 μm.

While example embodiments are disclosed herein, one of ordinary skill in the art appreciates that many variations that are in accordance with the present teachings are possible and remain within the scope of the appended claims. After a careful reading of the teachings of this specification and the drawings provided together herewith, such variations would be recognized by those of skill in the art. The embodiments therefore are not to be restricted except within the scope of the appended claims.

1. A method of providing a through-via in a semiconductor wafer, the method comprising:
forming a first via starting on a first side of a semiconductor wafer and extending a first depth into the semiconductor wafer from the first side of the semiconductor wafer, the first depth being less than a thickness of the semiconductor wafer and the first via having a first width in one direction;
providing a first conductive material in the first via;
providing one or more electronic components on the first side of the semiconductor wafer;
forming a second via starting on a second side of the semiconductor wafer opposite the first side and extending a second depth into the semiconductor wafer from the second side of the semiconductor wafer so as to expose the first via, the second via having a second width in one direction, the second width being greater than the first width; and
providing a second conductive material in the second via so as to make an electrical connection with the first conductive material deposited in the first via.

2. The method of claim 1, wherein forming the first via comprises:
forming a pattern mask on the first side of the substrate, the pattern mask having an opening where the first via is to be formed; and
etching the semiconductor wafer using an anisotropic plasma-based etch to form the first via.

3. The method of claim 1, wherein providing the first conductive material in the first via comprises depositing the first conductive material into the first via so as to close an opening of the first via from the first side of the wafer.

4. The method of claim 1, wherein providing the first conductive material in the first via comprises depositing the first conductive material into the first via so as to completely fill the first via.

5. The method of claim 1, further comprising removing a thickness of the semiconductor wafer from the second side of the semiconductor wafer before forming the second via.

6. The method of claim 1, wherein providing the second conductive material in the second via comprises depositing the second conductive material over the second side of the semiconductor substrate and so as to cover at least one sidewall of the second via.

7. The method of claim 1, wherein the step of providing one or more electronic components on the first side of the semiconductor wafer occurs before the step of forming the first via.

8. A device, comprising:
a substrate;
a first via provided in the substrate extending from a first side of the substrate to a first depth into the substrate, the first depth being less than a thickness of the substrate and the first via having a first width in one direction;
a first conductive material provided in the first via;
a second via provided in the substrate extending from a second side of the substrate to a second depth into the substrate, the second via having a second width in one direction, the second width being greater than the first width; and
a second conductive material provided in the second via so as to form an electrical connection with the first conductive material provided in the first via.

9. The device of claim 8, wherein the substrate is one of silicon, gallium arsenide, and indium phosphide.

10. The device of claim 8, wherein when the substrate has a thickness of about 100 μm, then the first depth is less than about 20 μm and the second depth is greater than about 75 μm.

11. The device of claim 8, wherein the first width is less than about 10 μm and the second width is greater than about 20 μm.

12. The device of claim 8, wherein the first conductive material closes an opening of the first via from the first side of the wafer.

13. The device of claim 8, wherein the first conductive material completely fills the first via.

14. An electrical device provided on a substrate, the electrical device comprising:
a first conductive electrode provided on a first side of the substrate;
a first via provided in the substrate extending from the first side of the substrate to a first depth into the substrate, the first depth being less than a thickness of the substrate, and the first via having a first width in one direction;
a first conductive material provided in the first via so as to form an electrical connection with the first conductive electrode;
a second via provided in the substrate extending from a second side of the substrate to a second depth into the substrate, the second via having a second width in one direction, the second width being greater than the first width; and
a second conductive material provided in the second via so as to form an electrical connection with the first conductive material provided in the first via.

15. The device of claim 14, further comprising:
an insulating layer disposed on the first conductive electrode; and
a second conductive electrode disposed on the insulating layer.

16. The device of claim 14, further comprising:
a third via provided in the substrate extending from the first side of the substrate to the first depth into the substrate, the third via having a third width in one direction, the third width being less than the second width; and
the third conductive material being provided in the third via,
wherein the second conductive material provided in the second via forms an electrical connection with the third conductive material provided in the third via.

17. The device of claim 16, wherein both the first and third vias are provided immediately beneath the first conductive electrode.

18. The device of claim 14, wherein the first via is provided laterally adjacent to the first conductive electrode, and is connected to the first conductive electrode by a conductive material provided on the first side of the substrate.

19. The device of claim 14, further comprising:
a second electrode disposed laterally with respect to the first electrode on the first side of the substrate; and
a gate electrode disposed on the first side of the substrate between the first and second electrodes;
wherein the device is a field-effect transistor; and
wherein the first and second electrodes comprises first source and first drain electrodes.

20. The device of claim 19, wherein the first electrode is the first source electrode, the device further comprising:
a second source electrode provided on the first side of the substrate;
a third via provided in the substrate extending from the first side of the substrate to the first depth into the substrate, the third via having a third width in one direction, the first conductive material being provided in the third via so as to form an electrical connection with the second source electrode; and
a fourth via provided in the substrate extending from the second side of the substrate to the second depth into the substrate, the fourth via having a fourth width in one direction, the fourth width being greater than the third width, and the second conductive material being provided in the fourth via so as to form an electrical connection with the first conductive material provided in the third via.
